(19) United States
(12) Patent Application Publication
(10) Pub. No.: US 2026/0277060 A1
(43) Pub. Date: Sep. 17, 2026

(54) TRANSPARENT DISPLAY DEVICE

(71) Applicant: Innolux Corporation, Miaoli County (TW)

(72) Inventors: CHUAN-CHI CHIEN, Miaoli County (TW); Chia-Hao Tsai, Miaoli County (TW)

(73) Assignee: Innolux Corporation, Miaoli County (TW)

(21) Appl. No.: 19/537,538

(22) Filed: Feb. 12, 2026

(30) Foreign Application Priority Data
Mar. 13, 2025 (CN) 202510296580.1

(51) Int. Cl. G02F 1/1343; G02F 1/1362; H10K 59/121; H10K 59/131

(52) U.S. Cl. CPC G02F 1/13439; G02F 1/136204; H10K 59/121; H10K 59/131

(57) ABSTRACT

A transparent display device is provided. The transparent display device includes a first transparent display, and has a non-transmitting region and multiple transmitting regions, wherein the transmitting regions are separated from each other by the non-transmitting region. The first transparent display includes a substrate having a first edge and multiple pixels. The pixels are disposed on the substrate and include a first pixel and a second pixel, wherein the pixels correspond to the non-transmitting region. The transmitting regions include a first transmitting region and a second transmitting region, at least a portion of the first transmitting region is disposed between the first pixel and the first edge, and the second transmitting region is disposed between the first pixel and the second pixel. The first transmitting region has a first area, the second transmitting region has a second area, and the first area is smaller than the second area.

### CROSS-REFERENCE TO RELATED APPLICATION

This application claims the priority benefit of China application serial no. 202510296580.1, filed on March 13, 2025. The entirety of the above-mentioned patent application is hereby incorporated by reference herein and made a part of this specification.

### BACKGROUND

### Technical Field

The disclosure relates to a display device, and in particular relates to a spliced transparent display device.

### Description of Related Art

In the current technology for manufacturing large-sized display devices, multiple small-sized display devices are usually spliced together to form a large-sized display device; however, during the process of splicing the display devices, a large amount of static electricity is easily generated due to the collision of the display devices. If static electricity cannot be discharged in time, it may easily cause damage to elements within the display device. Furthermore, in the context of large-sized transparent display device requirements, visual discrepancies at the seams constitute one of the significant concerns in spliced display devices. Therefore, how to minimize visual discrepancies at the seams while providing effective electrostatic protection has become an urgent issue requiring improvement.

### SUMMARY

A transparent display device which has a relatively good electrostatic protection effect without affecting the transmittance is provided in the disclosure.

According to some embodiments, a transparent display device is provided, which has a non-transmitting region and multiple transmitting regions, in which the transmitting regions are separated from each other by the non-transmitting region. Some embodiments of the disclosure provide a transparent display device including a first transparent display. The first transparent display includes a substrate and multiple pixels. The substrate has a first edge. The pixels are disposed on the substrate and include a first pixel and a second pixel, in which the pixels correspond to the non-transmitting region. The transmitting regions include a first transmitting region and a second transmitting region, at least a portion of the first transmitting region is disposed between the first pixel and the first edge, and the second transmitting region is disposed between the first pixel and the second pixel. The first transmitting region has a first area, the second transmitting region has a second area, and the first area is smaller than the second area.

According to some other embodiments, a transparent display device is provided, which has a non-transmitting region and multiple transmitting regions, in which the transmitting regions are separated from each other by the non-transmitting region. Some embodiments of the disclosure provide a transparent display device including a substrate, multiple pixels, multiple signal lines, and an electrostatic protection circuit. The pixels are disposed on the substrate and correspond to the non-transmitting region, in which at least one pixel includes at least one light-emitting element. The signal lines are disposed on the substrate and correspond to the non-transmitting region, in which at least one signal line is electrically connected to the at least one pixel. The electrostatic protection circuit is disposed on the substrate and corresponds to the non-transmitting region. The electrostatic protection circuit includes at least one electrostatic protection element, and the at least one electrostatic protection element is misaligned with the at least one light-emitting element in a normal direction of the substrate.

### BRIEF DESCRIPTION OF THE DRAWINGS

FIG. 1 is a top view schematic diagram of a spliced transparent display device of a first embodiment of the disclosure.

FIG. 2A is a partially enlarged top view schematic diagram of a first embodiment of a region R1 in the spliced transparent display device according to FIG. 1.

FIG. 2B is a partially enlarged top view schematic diagram of a first embodiment of a region R2 in the spliced transparent display device according to FIG. 1.

FIG. 3 is a top view schematic diagram of a spliced transparent display device of a second embodiment of the disclosure.

FIG. 4 is a partially enlarged top view schematic diagram of a second embodiment of a region R2 in the spliced transparent display device according to FIG. 1.

FIG. 5A is a partial enlarged top schematic diagram of the transparent display of an embodiment of the disclosure.

FIG. 5B is a partial enlarged top schematic diagram of the transparent display of another embodiment of the disclosure.

FIG. 6A to FIG. 6G are partial cross-sectional schematic diagrams of transparent displays of some embodiments of the disclosure.

### DETAILED DESCRIPTION OF DISCLOSED EMBODIMENTS

References of the exemplary embodiments of the disclosure are to be made in detail. Examples of the exemplary embodiments are illustrated in the drawings. If applicable, the same reference numerals in the drawings and the descriptions indicate the same or similar parts.

The disclosure may be understood by referring to the following detailed description in conjunction with the accompanying drawings. It should be noted that, for the ease of understanding by the readers and for the brevity of the accompanying drawings, multiple drawings in the disclosure only depict a portion of the electronic device, and the specific elements in the drawings are not drawn according to the actual scale. The number and size of each elements in the figures are for illustration purposes only, and are not intended to limit the scope of disclosure.

Certain terms may be used throughout the disclosure and the appended patent claims to refer to specific elements. It should be understood by those skilled in the art that electronic device manufacturers may refer to the same elements by different names. The disclosure does not intend to distinguish between elements that have the same function but have different names. In the following description and patent claims, words such as "comprising", "including", and "having" are open-ended words, so they should be interpreted as meaning "including but not limited to...". Accordingly, when the terms "comprising", "including", and/or "having" are used in the description of this disclosure, they designate the presence of the corresponding feature, region, step, operation and/or component, but do not exclude the presence of one or more of a corresponding feature, region, step, operation, and/or component.

In the disclosure, wordings used to indicate directions, such as “up,” “down,” “front,” “back,” “left,” and “right,” merely refer to directions in the accompanying drawings, so the directional wordings are used to illustrate rather than limit the disclosure. In the accompanying drawings, the drawings illustrate the general features of the methods, structures, and/or materials used in the particular embodiments. The drawings shall not be interpreted as defining or limiting the scope or nature covered by the embodiments. The relative sizes, thicknesses, and locations of the layers, regions, and/or structures may be reduced or enlarged for clarity.

When a corresponding component (e.g., a film layer or region) is referred to as being "on" another component, it may be directly on the other component or other components may be present therebetween. On the other hand, when a component is referred to as being "directly on" another member, there are no components in between unless otherwise stated in the specification. Additionally, when a component is referred to as being "on" another component, the two are in a top-down relationship when viewed from above, and the component may be above or below the other component, depending on the orientation of the device.

The terms "equal to" or "same", "substantially" or "generally" are interpreted as within 20% of a given value or range, or interpreted as within 10%, 5%, 3%, 2%, 1%, or 0.5% of the given value or range.

The terms such as "first", "second", etc. used in the description and the patent claims are used to modify elements, which do not imply and represent that the (or these) elements have any previous ordinal numbers, and also does not represent the order of a certain element and another element, or the order of the manufacturing method. The use of these ordinal numbers is to only clearly distinguish an element with a certain name from another element with the same name. The same terms may not be used in the patent claims and the description, and accordingly, the first component in the description may be the second component in the patent claims.

It should be noted that, in the following embodiments, the features in several different embodiments may be replaced, reorganized, and mixed to complete other embodiments without departing from the spirit of the disclosure. As long as the features of the various embodiments do not violate the spirit of the disclosure or conflict with one another, they may be mixed and matched arbitrarily.

The electrical connection or coupling described in the disclosure may refer to direct connection or indirect connection. In the case of a direct connection, the end points of two elements on a circuit directly connect to each other, or connect to each other through a conductive wire. In the case of indirect connection, a switch, a diode, a capacitor, an inductor, other suitable elements, or a combination thereof, is between the end points of two elements on a circuit.

In the disclosure, the thickness, length, width, and area may be measured by adopting a measurement method such as an optical microscope (OM), and the thickness may be measured from a cross-sectional image in an electronic microscope, but not limited thereto. In addition, any two values or directions used for comparison may have certain errors. If a first value is equal to a second value, it implies that there may be an error of about 10% between the first value and the second value; if a first direction is perpendicular to a second direction, an angle between the first direction and the second direction may be between 80 degrees and 100 degrees; if the first direction is parallel to the second direction, an angle between the first direction and the second direction may be between 0 degrees and 10 degrees.

The electronic device of the disclosure may include a display device, a light-emitting device, a sensing device, an antenna device, a touch device, a spliced device, or other suitable electronic device. The electronic device may be a bendable, stretchable, foldable, rollable and/or flexible electronic device. The display device may be applied to laptops, public displays, spliced displays, automotive displays, touch displays, transparent displays, double-sided displays, virtual reality displays, augmented reality displays, 3D displays, monochrome displays, color displays, televisions, monitors, mobile phones, tablets, light source modules, lighting equipment, and military equipment, but not limited thereto. The display device may include liquid crystal molecules, light-emitting diodes, a color conversion layer, other suitable display medium, or a combination thereof, but not limited thereto. The color conversion layer may include wavelength conversion materials and/or filter materials. The display device may include a liquid crystal display device, an electro-phoretic display device. The sensing device may be a sensing device for detecting capacitance changes, light, heat energy, or ultrasound, but not limited thereto. The sensing device may include a biosensor, a touch sensor, a fingerprint sensor, other suitable sensors, or a combination of the above types of sensors. It should be noted that the electronic device disclosed herein is exemplified by a transparent display device and a spliced transparent display device, but not limited thereto. The electrostatic protection circuits of all the embodiments disclosed herein may also be applicable to other types of electronic devices.

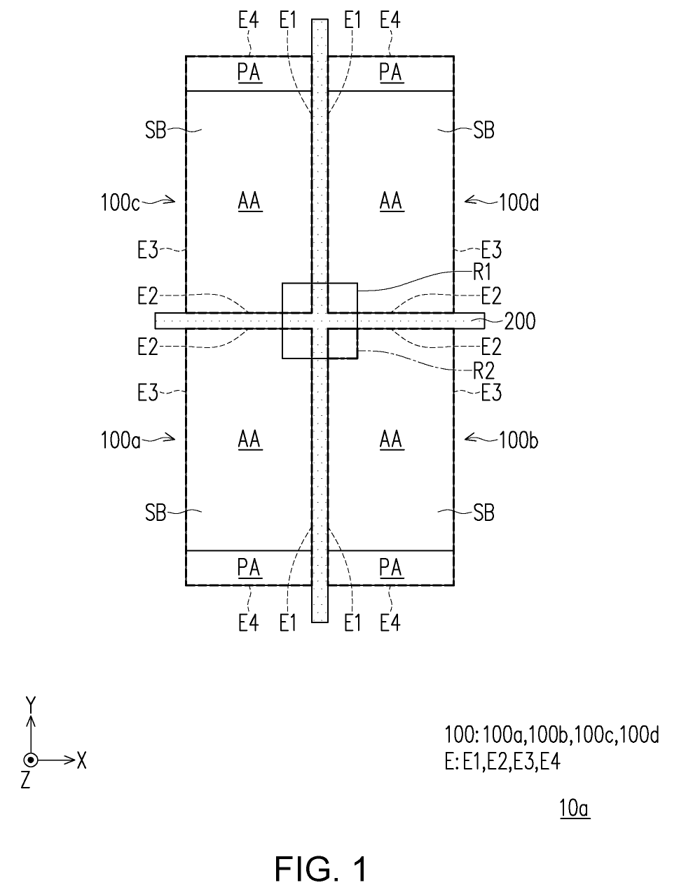

Referring to FIG. 1, a spliced transparent display device 10a is provided. In detail, the spliced transparent display device 10a includes multiple transparent displays 100 and a connecting member 200. The connecting member 200 is disposed between adjacent transparent displays 100. In this embodiment, the spliced transparent display device 10a includes four transparent displays 100a, 100b, 100c, and 100d. The two transparent displays 100a and 100b and the other two transparent displays 100c and 100d are arranged in a first direction X, and the two transparent displays 100a and 100c and the other two transparent displays 100b and 100d are arranged in a second direction Y to form a 2x2 arrayof transparent displays 100. In some embodiments, the shape of the transparent displays 100 may be rectangular. In this embodiment, the material of the connecting member 200 includes a transparent material. For example, the connecting member 200 may include acrylic resin, epoxy resin, silicone resin or other suitable transparent materials. The connecting member 200 may be configured to splice multiple small-sized displays and/or transparent displays into a large-sized spliced display device and/or spliced transparent display device.

In the present embodiment, the transparent display 100 includes an active area AA and a peripheral area PA, and the peripheral area PA is located at one side of the active area AA. In other words, the other three sides of the active area AA of the transparent display 100 may be configured to be spliced with other transparent displays. For example, the active area AA of the transparent display 100a is spliced with the active area AA of the transparent display 100b and the active area AA of the transparent display 100c through the connecting member 200. In some embodiments, the peripheral areas PA of two transparent displays 100 may be spliced together through the connecting member 200.

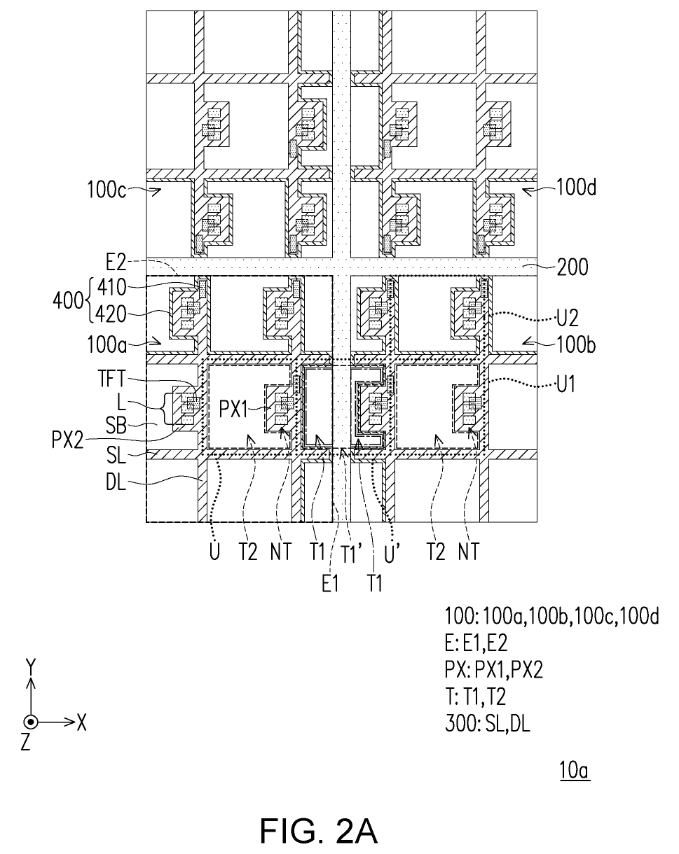

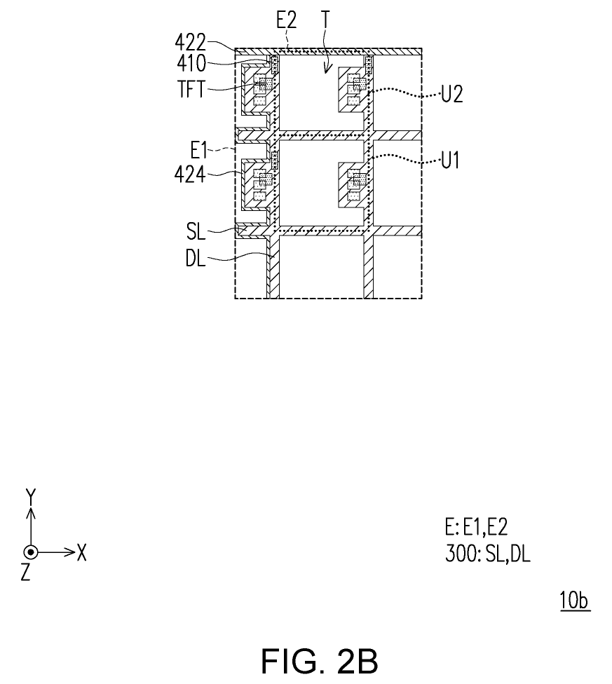

Referring to FIG. 2A, the active areas AA of the transparent displays 100a, 100b, 100c, and 100d of the present embodiment may include a non-transmitting region NT and multiple transmitting regions T. The non-transmitting region NT is a region defined by the non-transmitting material and/or the non-transmitting element, and the transmitting region T is a region outside the non-transmitting region NT. Multiple transmitting regions T may be separated from each other by the non-transmitting region NT. In detail, the non-transmitting region NT may have a grid structure, and the transmitting regions T may each be a grid in the grid structure. In this embodiment, a non-transmitting element may include a signal line, a light-emitting element, or other electronic elements (e.g., a capacitor, a resistor, an inductor, a diode, a transistor, or a sensor). The non-transmitting material may include metal, light-shielding material, and/or other materials that affect light transmission.

Please continue to refer to FIG. 2A, from another perspective, the transparent display 100a of this embodiment includes a substrate SB and multiple pixels PX.

Referring to FIG. 1, the substrate SB has multiple edges E (e.g., a first edge E1, a second edge E2, a third edge E3, and a fourth edge E4). The first edge E1 may be the edge of the transparent display 100a facing the transparent display 100b, the second edge E2 may be the edge of the transparent display 100a facing the transparent display 100c, and the third edge E3 and the fourth edge E4 may be respectively opposite to the first edge E1 and the second edge E2. Taking the transparent display 100a shown in FIG. 1 and FIG. 2A as an example, the peripheral area PA of the transparent display 100a is located at the fourth edge E4 of the substrate SB.

In this embodiment, the transmitting region T of the transparent display 100a includes transmitting regions T1 and T2. The area of the transmitting region T1 is smaller than the area of the transmitting region R2, and the shortest distance between the transmitting region T1 and the first edge E1 is less than the shortest distance between the transmitting region T2 and the first edge E1. For example, the outer edge of one side of the transmitting region T1 overlaps with the first edge E1, and the shortest distance between the outer edge of one side of the transmitting region T2 and the first edge E1 is greater than 0. In some embodiments, at least a portion of the transmitting region T1 is located between the first edge E1 and the non-transmitting region NT, and the non-transmitting region NT is located between the transmitting regions T1 and T2.

The pixels PX are disposed on the substrate SB and correspond to the non-transmitting region NT. The pixel PX includes at least one light-emitting element L. For example, the pixel PX may include red, green, and blue light-emitting elements L. The light-emitting element L may include an organic light-emitting diode (OLED) or an inorganic light-emitting diode (LED), such as a mini LED or a micro LEDs, a quantum dot (QD), a quantum dot light-emitting diode (QDLED), fluorescence, phosphor, other suitable materials or a combination of the above materials. In some embodiments, the pixel PX may further include an active element TFT (e.g., a switching element, a driving element and/or a light-emitting control element) for controlling the light-emitting element L, a capacitor electrically connected to the active element TFT, and/or a connection pad for bonding the light-emitting element L. In some embodiments, the active element TFT and the light-emitting element L at least partially overlap. In the disclosure, the number of active elements TFT is not limited to that shown in the figure. In some embodiments, the red light-emitting element, the green light-emitting element, and the blue light-emitting element each have a corresponding active element TFT.

In this embodiment, the pixels PX include a first pixel PX1 and a second pixel PX2. The first pixel PX1 is between the second pixel PX2 and the first edge E1 and is the pixel closest to the first edge E1. At least a portion of the transmitting region T1 is disposed between the first pixel PX1 and the first edge E1, and the transmitting region T2 is disposed between the first pixel PX1 and the second pixel PX2.

In this embodiment, the pixel PX may be offset from the data line DL. Specifically, the data line DL does not pass through the center of the pixel PX. In some other embodiments, the data line DL may pass through the center of the pixel PX.

Please continue to refer to FIG. 2A, in this embodiment, the transparent display 100a of this embodiment further includes multiple signal lines 300.

The signal lines 300 are disposed on the substrate SB and correspond to the non-transmitting region NT. In this embodiment, a signal line 300 include a scan line SL extending along the first direction X and a data line DL extending along the second direction Y. Multiple units U are defined by the scan lines SL and the data lines DL and arranged in an array.

In some embodiments, the signal line 300 further includes a light-emitting control line, a power voltage line, a reference voltage line and/or other suitable wirings.

In some embodiments, multiple signal lines 300 are electrically connected to the pixels PX. For example, the scan lines SL and the data lines DL in the signal lines 300 are electrically connected to the active elements TFT in the pixels PX, and the light-emitting control lines in the signal lines 300 are electrically connected to the light-emitting elements L.

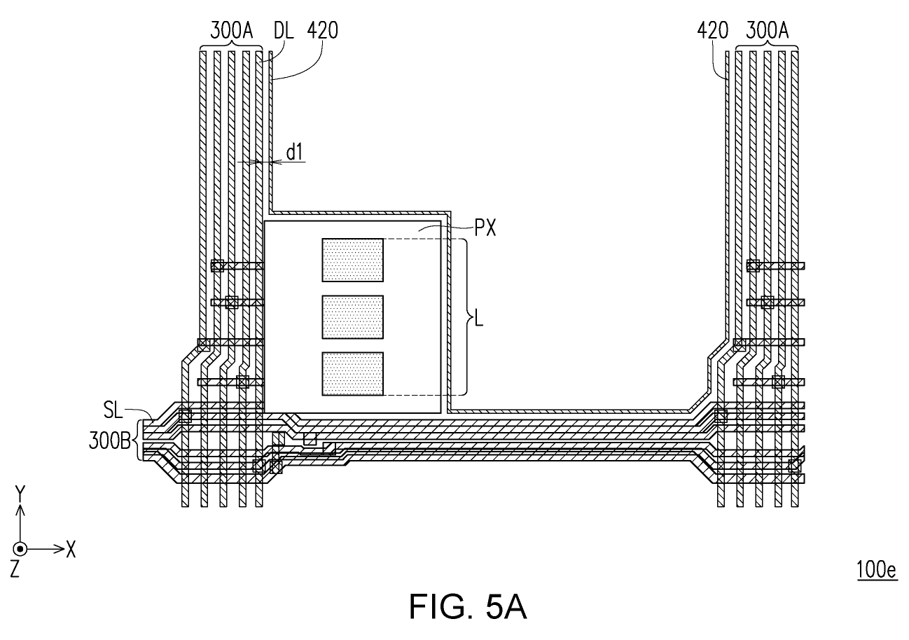

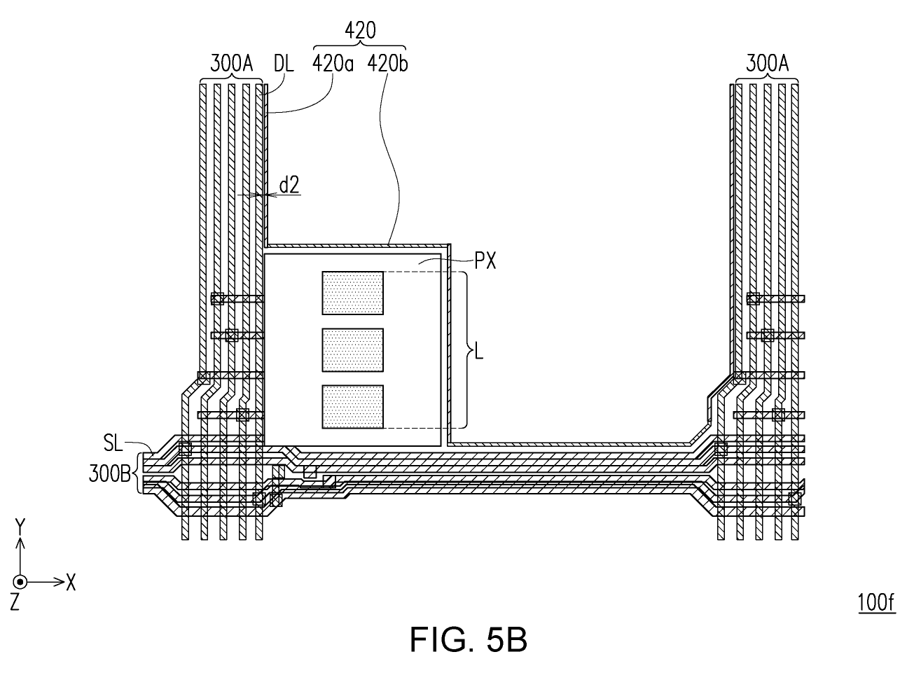

In some embodiments, the signal lines 300 with different or same functions may form a subset and be disposed between adjacent transmitting regions T, such as the signal lines 300A and/or the signal lines 300B in FIG. 5A and FIG. 5B. In some other embodiments, the number of the signal line 300 disposed between adjacent transmitting regions T may be one.

In this embodiment, the transparent display 100a may include multiple units U arranged in an array. One of the units U includes a transmitting region T2 and a portion of the non-transmitting region NT surrounding the transmitting region T2. Specifically, the units U may be defined by interlaced signal lines 300 (e.g., scan lines SL and data lines DL), such that the transmitting region T2 and the surrounding non-transmitting region NT form a unit U, with adjacent units U each equally dividing the peripheral non-transmitting region NT.

From another perspective, a unit U includes a pixel (e.g., pixel PX1) and a transmitting region T2. In some embodiments, the proportion of the transmitting region T2 in a unit U is greater than or equal to 65%.

In addition, in this embodiment, when the transparent display 100a and the transparent display 100b are spliced into a transparent spliced display device, the adjacent transmitting regions T1 of the transparent display 100a and the transparent display 100b and the connecting member 200 made of transparent material may be combined into a splicing transmitting region T1'. In this embodiment, the splicing transmitting region T1' may be substantially surrounded by the non-transmitting region NT. The splicing transmitting region T1' and the surrounding non-transmitting region NT form a splicing unit U', with adjacent splicing units U' each equally dividing the peripheral non-transmitting region NT.

Similarly, from another perspective, a splicing unit U' includes a pixel PX and a splicing transmitting region T1'. In some embodiments, the proportion of the splicing transmitting region T1' in a splicing unit U' is greater than or equal to 65%. In the disclosure, the splicing unit U' is substantially the same as the unit U, and the splicing transmitting region T1' is substantially the same as the transmitting region T2. For example, the ratio of the area of the splicing unit U' to the area of the unit U is greater than 0.75 and less than 1.25. In some embodiments, the above ratio is greater than 0.85 and less than 1.15. For example, the ratio of the area of the splicing transmitting region T1' to the area of the transmitting region T2 is greater than 0.75 and less than 1.25. In some embodiments, the above ratio is greater than 0.85 and less than 1.15. Based on this, this is conducive to reducing the visual discrepancies between the splicing seam and the active area AA, thereby improving the display quality of the spliced transparent display device 10a.

Please continue to refer to FIG. 2A, in this embodiment, the transparent display 100a further includes an electrostatic protection circuit 400.

The electrostatic protection circuit 400 is disposed on the substrate SB and corresponds to the non-transmitting region NT. In this embodiment, the electrostatic protection circuit 400 includes at least one electrostatic protection element 410 and an electrostatic discharge wire 420.

The at least one electrostatic protection element 410 is electrically connected to the electrostatic discharge wire 420. The material of the electrostatic discharge wire 420 may include metal or other conductive materials. In the present embodiment, the at least one electrostatic protection element 410 overlaps at least one of the signal lines 300 in the normal direction Z of the substrate SB. The electrostatic protection element 410 may be a diode. In some embodiments, the electrostatic protection element 410 may be a back-to-back diode. In this embodiment, the electrostatic protection element 410 is misaligned with the light-emitting element L in the normal direction Z of the substrate SB. That is, although the electrostatic protection element 410 and the light-emitting element L are both disposed corresponding to the non-transmitting region NT, the electrostatic protection element 410 and the light-emitting element L do not overlap. In some embodiments, the electrostatic protection element 410 is disposed correspondingly at the end of the non-transmitting region NT (i.e., the non-transmitting region NT adjacent to the first edge E1, the second edge E2 and/or the third edge E3), and is misaligned with the end of the signal line 300, so that the static electricity generated during splicing may be effectively discharged to improve the yield of the spliced display device. In some embodiments, the electrostatic protection element 410 may not be disposed inside the non-transmitting region NT (i.e., the non-transmitting region NT away from the first edge E1, the second edge E2 and/or the third edge E3). The electrostatic discharge wire 420 is disposed between one of the signal lines 300 and one of the transmitting regions T. In this embodiment, the electrostatic discharge wire 420 is disposed adjacent to the first edge E1, the second edge E2, and the third edge E3 of the substrate SB of the transparent display 100a. The electrostatic discharge wire 420 may have a suitable shape such as a ring, a U-shape, an inverted U-shape, etc. In this embodiment, the electrostatic discharge wire 420 of the transparent display 100a is adjacent to and surrounds the signal lines 300 and/or the pixels PX that are closest to the first edge E1, the second edge E2 and the third edge E3 of the substrate SB.

Based on the above, the electrostatic protection element 410 and the electrostatic discharge wire 420 may be disposed in the active area AA of the transparent display 100a, in which the electrostatic discharge wire 420 is located at the periphery of the active area AA. Therefore, by electrically connecting the electrostatic discharge wire 420 to the electrostatic protection element 410, when an excessively high voltage pulse is to be transmitted to at least one of the signal lines 300, the electrostatic discharge wire 420 may form a relatively low impedance current path with the electrostatic protection element 410 to reduce the instantaneous current from entering the active area AA, thereby reducing the possibility of damage to the active element TFT, the light-emitting element L and/or other electronic elements within the active area AA.

Furthermore, in this embodiment, the electrostatic discharge wire 420 is disposed adjacent to the signal lines 300 and/or the pixels PX close to the first edge E1, the second edge E2 and the third edge E3 of the substrate SB, thereby reducing circumstances affecting the aperture ratio of units U' adjacent to the edge E of the substrate SB.

Referring to FIG. 2, the main difference between the spliced transparent display device 10b and the spliced transparent display device 10a is that the electrostatic discharge wires 420 have different line widths. In some embodiments, in a top-view direction, a portion of the electrostatic discharge wire 420 is located between an edge of the substrate SB (e.g., the second edge E2) and at least a portion of the transmitting region T adjacent to the edge of the substrate.

In this embodiment, the electrostatic discharge wire 420 includes electrostatic discharge wires 422 and 424. In a top-view direction, the electrostatic discharge wires 422 and 424 are disposed at different positions on the substrate and are electrically connected to each other. The static discharge wire 422 is disposed adjacent to the second edge E2 of the substrate SB of the transparent display 100b, and the static discharge wire 424 is disposed adjacent to the first edge E1 of the substrate SB of the transparent display 100a.

The line width of the electrostatic discharge wire 422 is different from the line width of the electrostatic discharge wire 424 to effectively compensate for the difference in transmitting regions of different units. In this embodiment, the line width of the electrostatic discharge wire 422 is greater than or equal to twice the line width of the electrostatic discharge wire 424. By designing the line width of the electrostatic discharge wire 422 to be greater than the line width of the electrostatic discharge wire 424, the proportion of the non-transmitting region NT adjacent to the second edge E2 of the substrate SB in the unit U2 is increased, so that the aperture ratio of the unit U2 adjacent to the second edge E2 of the substrate SB may be substantially equal to the aperture ratio of the unit U1 away from the second edge E2 of the substrate SB. In this way, the possibility of visual discrepancies at the splicing seams may be reduced, thereby improving the display quality of the spliced transparent display device 10b.

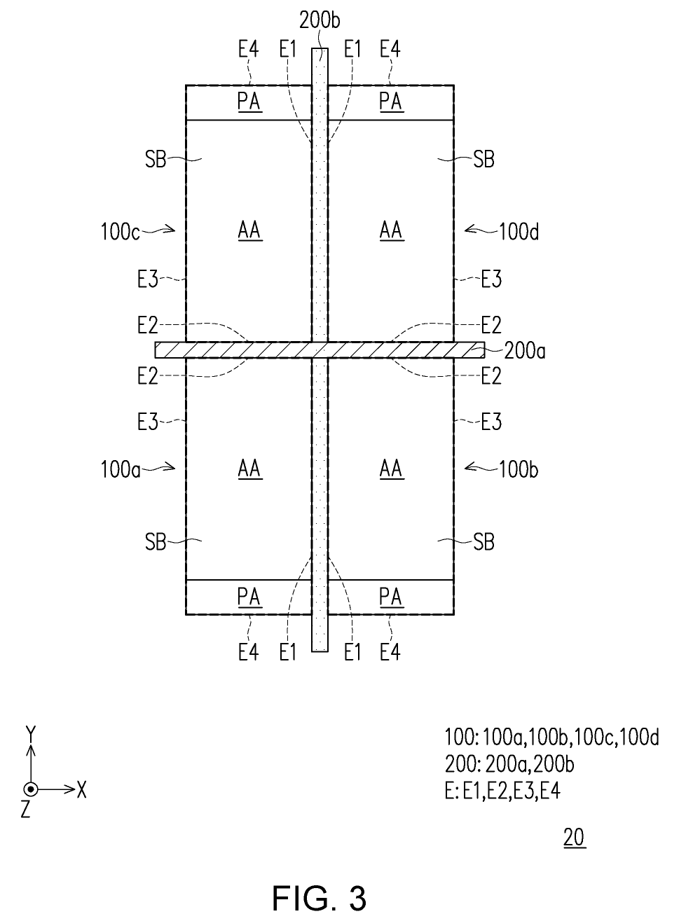

Referring to FIG. 3, the main difference between the spliced transparent display device 20 and the spliced transparent display device 10a is that a portion of the connecting member 200 includes a non-transparent material.

In this embodiment, the connecting member 200 includes connecting members 200a and 200b, in which the connecting member 200a includes a non-transparent material, and the connecting member 200b includes a transparent material. In this embodiment, the connecting member 200a is configured to connect the second edge E2 of the substrate SB of the transparent display 100a with the second edge E2 of the substrate SB of the display 100c, and is configured to connect the second edge E2 of the substrate SB of the transparent display 100b with the second edge E2 of the substrate SB of the display 100d.

In this embodiment, by designing the connecting member 200a configured to connect the second edges E2 of the substrates SB of adjacent transparent displays 100 to include a non-transparent material, the proportion of the non-transmitting region NT adjacent to the second edge E2 of the substrate SB in the unit U2 may be increased, so that the aperture ratio of the unit U2 adjacent to the second edge E2 of the substrate SB is substantially equal to the aperture ratio of the unit U1 away from the second edge E2 of the substrate SB. In this way, the possibility of visual discrepancies at the splicing seams may be reduced, thereby improving the display quality of the spliced transparent display device 20.

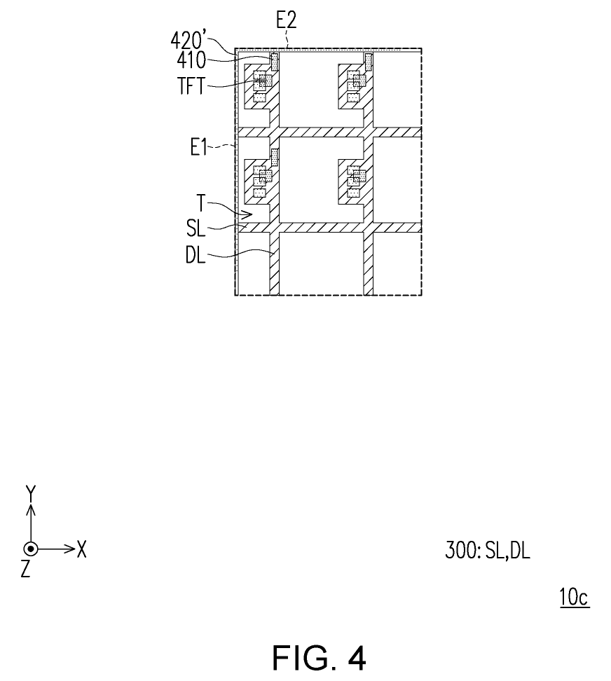

Referring to FIG. 4, the main difference between the spliced transparent display device 10c and the spliced transparent display device 10b is that the electrostatic discharge wire 420' is made of transparent conductive material and disposed corresponding to the transmitting region T.

For example, the material of the electrostatic discharge wire 420' may include indium tin oxide. Based on this, when the transparent display 100a and the transparent display 100b form a spliced transparent display device, the adjacent transmitting regions T of the transparent display 100a and the transparent display 100b (including the electrostatic discharge wire 420' made of transparent conductive material) and the connecting member 200 made of transparent material may be combined into a splicing transmitting region, reducing the possibility of visual discrepancies at the splicing seams. In some embodiments, the electrostatic discharge wire 420' may be designed to have a grid structure to further reduce the possibility of being observed by the user. In addition, in some embodiments, the electrostatic discharge wire 420' may be electrically connected to at least one of the signal lines 300 to reduce its impedance.

Referring to FIG. 5A, the main difference between the transparent display 100e and the transparent display 100a is that the electrostatic discharge wire 420 is made of the same layer and belongs to the same layer as the signal lines 300A extending in the direction Y or the same layer as the signal lines 300B extending in the direction X.

Specifically, the signal lines 300 may include multiple signal lines 300B extending in direction X (e.g., scan lines SL and/or other types of signal lines) and multiple signal lines 300A extending in direction Y (e.g. data lines DL and/or other types of signal lines). Taking FIG. 5A as an example, the signal lines 300B extending in direction X are made of a first metal layer, the electrostatic discharge wire 420 and the signal lines 300A extending in direction Y are made of a second metal layer, and in the normal direction Z of the substrate SB, the first metal layer is disposed between the substrate SB and the second metal layer. In this embodiment, there is a shortest distance d1 between the electrostatic discharge wire 420 and the data line DL made of the same metal layer. The shortest distance d1 is greater than or equal to 3 μm and less than or equal to 8 μm. When the shortest distance d1 is within the above range, the mutual interference between different signals of unit U may be reduced without sacrificing too much aperture ratio.

Referring to FIG. 5B, the main difference between the transparent display 100f and the transparent display 100e is that the electrostatic discharge wire 420 is made of multiple different layers. For example, a portion of the electrostatic discharge wire 420 and the signal lines 300B extending in the direction X belong to the same layer, and another portion of the electrostatic discharge wire 420 and the signal lines 300A extending in the direction Y belong to the same layer.

In this embodiment, the plurality of signal lines 300B extending in the direction X belong to the first metal layer, and the plurality of signal lines 300A extending in the direction Y belong to the second metal layer.

In this embodiment, the electrostatic discharge wire 420 includes electrostatic discharge wire segments 420a and 420b. The electrostatic discharge wire segment 420a is a portion of the electrostatic discharge wire 420 relatively close to the signal lines 300A extending in the direction Y, and the electrostatic discharge wire segment 420b is a portion of the electrostatic discharge wire 420 relatively close to the signal lines 300B extending in the direction X. In some embodiments, the electrostatic discharge wire segments 420a and 420b adjacent to each other may be electrically connected to each other via a through hole located in the insulating layer.

Based on this, in this embodiment, the electrostatic discharge wire segment 420a is designed to belong to a different layer from the signal lines 300A (e.g., the data line DL) extending in the direction Y, and the electrostatic discharge wire segment 420b is designed to belong to a different layer from the signal lines 300B (e.g., the scan line SL) extending in the direction X, so that the electrostatic discharge wire 420 may be disposed relatively close to the signal lines 300 to increase the aperture ratio. In this embodiment, the distance d2 between the electrostatic discharge wire segment 420a and the data line DL in the direction X is less than or equal to 2 μm, and the distance d2 between the electrostatic discharge wire segment 420b and the scan line SL in the direction Y is less than or equal to 2 μm. Since the electrostatic discharge wire segment 420a and the data line DL belong to different layers, the electrostatic discharge wire segment 420a and the data line DL may partially overlap in the normal direction Z of the substrate SB.

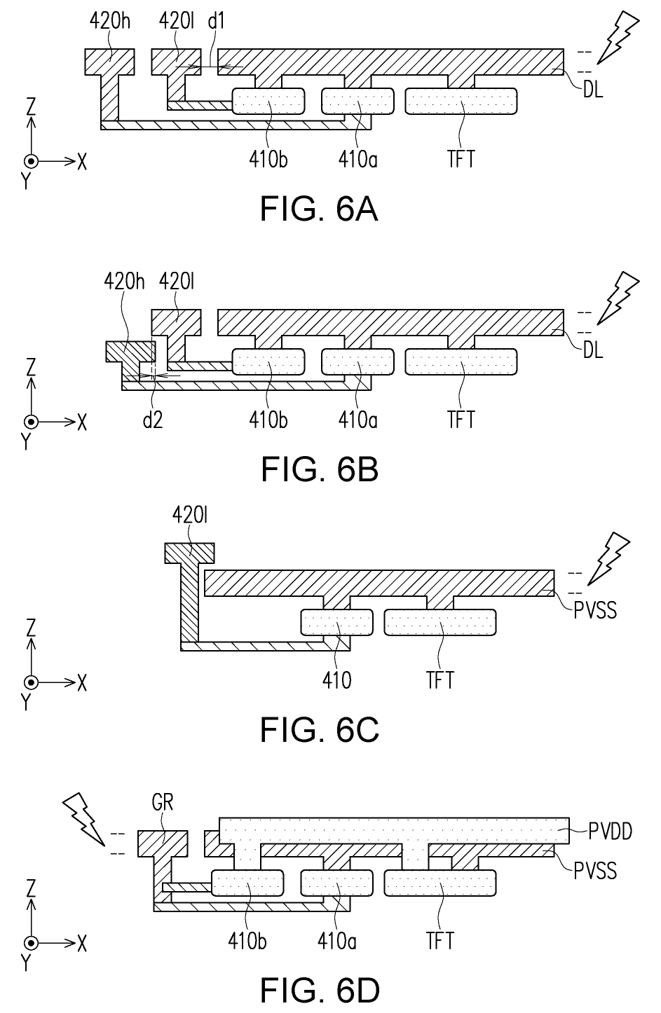

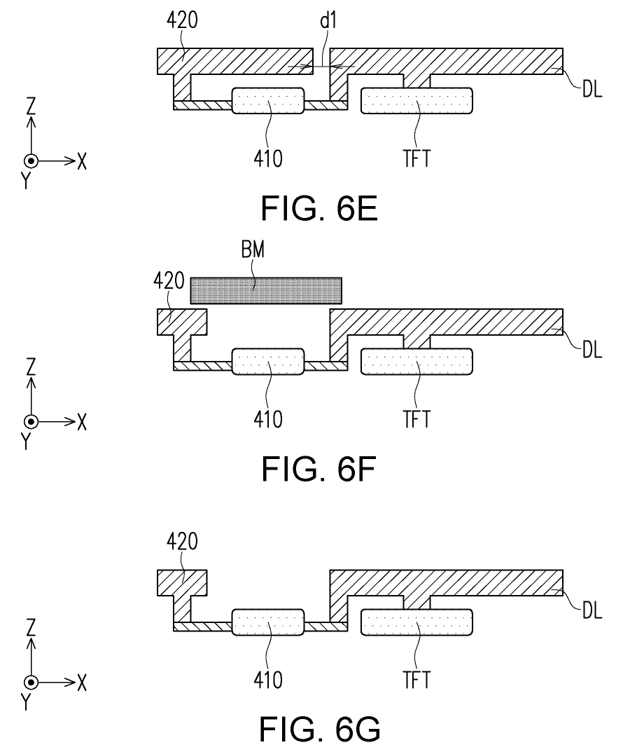

Referring to FIG. 6A, in this embodiment, the signal lines 300 include a data line DL, and the electrostatic discharge wire 420 includes a high level voltage line 420h and a low level voltage line 420l. The data line DL, the high level voltage line 420h and the low level voltage line 420l are all made of the same layer.

The data line DL is electrically connected to the active element TFT, and is electrically connected to at least one electrostatic protection element 410. In this embodiment, the electrostatic protection element 410 includes diodes 410a and 410b. A first end of the diode 410a is electrically connected to the data line DL, and a second end of the diode 410a is electrically connected to the high level voltage line 420h. A first end of the diode 410b is electrically connected to the data line DL, and a second end of the diode 410b is electrically connected to the low level voltage line 420l. In this embodiment, there is a shortest distance d1 between the electrostatic discharge wire 420 (low level voltage line 420l) and the data line DL. In the present embodiment, the distance d1 between the electrostatic discharge wire 420 (low level voltage line 420l) and the data line DL in the direction X is 3 μm to 8 μm, and the distance d1 between the low level voltage line 420l and the high level voltage line 420h may also be 3 μm to 8 μm.

In this embodiment, at least one electrostatic protection element 410 may be disposed close to the end of the non-transmitting region NT. In the embodiment, at least one electrostatic protection element 410 overlaps at least one of the signal lines 300 in the normal direction Z of the substrate SB. As shown in FIG. 6A, the electrostatic protection element 410 overlaps the data line DL in the normal direction Z of the substrate SB.

In this embodiment, the electrostatic protection element 410 and the active element TFT are made through the same layer. For example, the gate of the electrostatic protection element 410 and the gate of the active element TFT are in the same layer, and the semiconductor layer of the electrostatic protection element 410 and the semiconductor layer of the active element TFT are in the same layer.

Referring to FIG. 6B, the main difference between the transparent display of this embodiment and the transparent display of FIG. 6A is that the data line DL and the low level voltage line 420l are disposed on the high level voltage line 420h and are made of the same layer. The high level voltage line 420h and the low level voltage line 420l may be switched in layers.

Through the above configuration, the distance between the high level voltage line 420h and the low level voltage line 420l in the direction X may be reduced to further improve the aperture ratio of the unit U. In this embodiment, the high level voltage line 420h at least partially overlaps with the low level voltage line 420l.

Referring to FIG. 6C, the main difference between the transparent display of this embodiment and the transparent display of FIG. 6A is that the signal lines 300 include a low level power line PVSS, the low level power line PVSS is electrically connected to one end of the light-emitting element L, and the electrostatic discharge wire 420 is a low level voltage line 420l. The electrostatic protection element 410 is electrically connected to the low level power line PVSS and the low level voltage line 420l. The low level power line PVSS and the low level voltage line 420l may be made of the same or different layers according to product requirements. The low level power line PVSS and the low level voltage line 420l may be made of different layers. In some embodiments, this architecture may also replace the low level power line PVSS with the high level power line PVDD, and replace the low level voltage line 420l with the high level voltage line 420h to achieve the effect of electrostatic protection.

Through the above configuration, the number of the electrostatic discharge wires 420 disposed may be reduced to further improve the opening ratio of the unit U.

Referring to FIG. 6D, the main difference between the transparent display of this embodiment and the transparent display of FIG. 6A is that the signal lines 300 include a low level power line PVSS and a high level power line PVDD, and the electrostatic discharge wire 420 includes a guard ring GR. The low level power line PVSS and the high level power line PVDD are electrically connected to two ends of the light-emitting element L. In some embodiments, the guard ring GR may be a ground line. A first end of the diode 410a is electrically connected to the low level power line PVSS, and a second end of the diode 410a is electrically connected to the guard ring GR. A first end of the diode 410b is electrically connected to the high level power line PVDD, and a second end of the diode 410b is electrically connected to the guard ring GR. The low level power line PVSS and the guard ring GR may be made of the same layer, and the high level power line PVDD and the low level power line PVSS are in different layers. In some embodiments, the low level power line PVSS, the guard ring GR, and the high level power line PVDD may be made of the same layer.

Through the above configuration, when the guard ring GR is subjected to a large amount of static electricity, the effect of electrostatic protection may be achieved through the low level power line PVSS and the high level power line PVDD. Referring to FIG. 6E, FIG. 6F, and FIG. 6G, at least one electrostatic protection element 410 is misaligned with the end of at least one of the signal lines 300. Specifically, at least one electrostatic protection element 410 may be adjacent to an end of at least one of the signal lines 300 in the normal direction Z of the substrate SB but may not overlap the at least one of the signal lines 300.

In FIG. 6E, the electrostatic discharge wire 420 may extend in a direction X, such that at least one electrostatic protection element 410 overlaps the electrostatic discharge wire 420 in a normal direction Z of the substrate SB. Based on this, at least one electrostatic protection element 410 may be shielded by the electrostatic discharge wire 420 in the normal direction Z.

In FIG. 6F, the transparent display further includes a shielding layer BM. The shielding layer BM shields at least one electrostatic protection element 410 in the normal direction Z of the substrate SB. The shielding layer BM may include a light shielding material. For example, the material of the light shielding structure BM includes black resin or a metal material with low reflectivity.

In FIG. 6G, at least one electrostatic protection element 410 may be exposed by the electrostatic discharge wire 420 in the normal direction Z of the substrate SB.

Based on the above, in the transparent display device provided in some embodiments of the disclosure, by disposing the electrostatic discharge wires adjacent to multiple signal lines and/or multiple pixels close to the splicing edge of the substrate, it is possible to reduce circumstances affecting the aperture ratio of the units adjacent to the edge of the substrate.

Furthermore, in a transparent display device that is spliced to each other, the small-area transmitting regions and connecting members of the two adjacent transparent displays may be combined into a splicing transmitting region, and the line width of the electrostatic discharge wire, the material of the connecting member, the material of the electrostatic discharge wire and/or the layer of the electrostatic discharge wire may be adjusted so that the ratio of the area of the above-mentioned splicing transmitting region to the area of the transmitting region inside the active area (i.e., the area outside the splicing edge in the active area) is greater than 0.75 and less than 1.25, which may reduce the possibility of visual discrepancies at the splicing seams and improve the display quality of the transparent display device provided by some embodiments of the disclosure.

Finally, it should be noted that the foregoing embodiments are only used to illustrate the technical solutions of the disclosure, but not to limit the disclosure; although the disclosure has been described in detail with reference to the foregoing embodiments, persons of ordinary skill in the art should understand that the technical solutions described in the foregoing embodiments may still be modified, or parts or all of the technical features thereof may be equivalently replaced; however, these modifications or substitutions do not deviate the essence of the corresponding technical solutions from the scope of the technical solutions of the embodiments of the disclosure.

What is claimed is:

1. A transparent display device, comprising:
a first transparent display, having a non-transmitting region and a plurality of transmitting regions, wherein the transmitting regions are separated from each other by the non-transmitting region, the first transparent display comprises:
a substrate, having a first edge; and
a plurality of pixels, disposed on the substrate and comprise a first pixel and a second pixel, wherein the pixels correspond to the non-transmitting region;
wherein, the transmitting regions comprise a first transmitting region and a second transmitting region, at least a portion of the first transmitting region is disposed between the first pixel and the first edge, and the second transmitting region is disposed between the first pixel and the second pixel,
wherein, the first transmitting region has a first area, the second transmitting region has a second area, and the first area is smaller than the second area.

2. The transparent display device according to claim 1, further comprising:
a second transparent display, adjacent to the first transparent display; and
a connecting member, disposed between the first transparent display and the second transparent display,
wherein a shortest distance between the first transmitting region of the first transparent display and the first edge is less than a shortest distance between the second transmitting region of the first transparent display and the first edge,
wherein the first transparent display and the second transparent display are spliced together through the connecting member, so that the first transmitting region of the first transparent display, the first transmitting region of the second transparent display and the connecting member are combined to form a splicing transmitting region,
wherein, a ratio of an area of the splicing transmitting region to an area of the second transmitting region is greater than 0.75 and less than 1.25.

3. The transparent display device according to claim 1, wherein the first transparent display further comprises:
an electrostatic protection circuit, disposed on the substrate and corresponding to the non-transmitting region, wherein the electrostatic protection circuit comprises at least one electrostatic protection element and an electrostatic discharge wire, and the at least one electrostatic protection element is electrically connected to the electrostatic discharge wire.

4. The transparent display device according to claim 3, wherein the first transparent display further comprises:
a plurality of signal lines, corresponding to the non-transmitting region, wherein the at least one electrostatic protection element overlaps at least one of the signal lines in a normal direction of the substrate.

5. The transparent display device according to claim 3, wherein the first transparent display further comprises:
a plurality of signal lines, corresponding to the non-transmitting region, wherein the at least one electrostatic protection element is misaligned with an end of at least one of the signal lines in a normal direction of the substrate.

6. The transparent display device according to claim 3, wherein the first transparent display further comprises:
a plurality of signal lines, corresponding to the non-transmitting region, wherein at least a portion of the electrostatic discharge wire is disposed between the signal lines and the first transmitting region.

7. The transparent display device according to claim 3, wherein the electrostatic discharge wire comprises a first line width and a second line width, and the first line width is different from the second line width.

8. The transparent display device according to claim 7, wherein the first line width is greater than or equal to twice the second line width.

9. The transparent display device according to claim 2, wherein the ratio of the area of the splicing transmitting region to the area of the second transmitting region is greater than 0.85 and less than 1.15.

10. The transparent display device according to claim 3, wherein a shape of the electrostatic discharge wire is a ring, a U-shape, an inverted U-shape, or a combination thereof.

11. The transparent display device according to claim 3, wherein the connecting member comprises a first connecting member and a second connecting member, the first connecting member extends in a first direction and comprises a non-transparent material, and the second connecting member extends in a second direction and comprises a transparent material, wherein the first direction is different from the second direction.

12. A transparent display device, having a non-transmitting region and a plurality of transmitting regions, wherein the transmitting regions are separated from each other by the non-transmitting region, and the transparent display device comprises:
a substrate;
a plurality of pixels, disposed on the substrate and corresponding to the non-transmitting region, wherein at least one pixel comprises at least one light-emitting element;
a plurality of signal lines, disposed on the substrate and corresponding to the non-transmitting region, wherein at least one signal line is electrically connected to the at least one pixel; and
an electrostatic protection circuit, disposed on the substrate and corresponding to the non-transmitting region, wherein the electrostatic protection circuit comprises at least one electrostatic protection element, and the at least one electrostatic protection element is misaligned with the at least one light-emitting element in a normal direction of the substrate.

13. The transparent display device according to claim 12, wherein the at least one electrostatic protection element overlaps at least one of the signal lines in the normal direction of the substrate.

14. The transparent display device according to claim 12, wherein the at least one electrostatic protection element is misaligned with an end of at least one of the signal lines in the normal direction of the substrate.

15. The transparent display device according to claim 12, wherein the electrostatic protection circuit further comprises an electrostatic discharge wire, and the electrostatic discharge wire is electrically connected to the at least one electrostatic protection element.

16. The transparent display device according to claim 15, wherein at least a portion of the electrostatic discharge wire is disposed between the signal lines and at least one of the transmitting regions.

17. The transparent display device according to claim 15, wherein the electrostatic discharge wire comprises a first line width and a second line width, and the first line width is different from the second line width.

18. The transparent display device according to claim 15, wherein the at least one electrostatic protection element is shielded by the electrostatic discharge wire in the normal direction of the substrate.

19. The transparent display device according to claim 15, wherein the at least one electrostatic protection element is exposed by the electrostatic discharge wire in the normal direction of the substrate.

20. The transparent display device according to claim 12, further comprising:
a shielding layer, disposed on the substrate and shielding the at least one electrostatic protection element in the normal direction of the substrate.
